(19) United States
(12) Patent Application Publication
(10) Pub. No.: US 2026/0242934 A1
(43) Pub. Date: Aug. 20, 2026

(54) METAL DEPOSITION FOR VOIDLESS GAP FILL

(71) Applicant: Applied Materials, Inc., Santa Clara, CA (US)

(72) Inventors: Haoming Yan, Santa Clara, CA (US); Jianqiu Guo, San Jose, CA (US); Shih Chung Chen, Cupertino, CA (US); Sourav Garg, San Jose, CA (US); Janardhan Devrajan, Santa Clara, CA (US); Ziyi Zhao, Sunnyvale, CA (US); Ya-Hsi Hwang, Sunnyvale, CA (US); Derrick ShaoHeng Liu, Sunnyvale, CA (US); Haoyan Sha, San Jose, CA (US); Dong Wang, San Mateo, CA (US)

(73) Assignee: Applied Materials, Inc., Santa Clara, CA (US)

(21) Appl. No.: 19/056,914

(22) Filed: Feb. 19, 2025

(51) Int. Cl. C23C 16/04; C23C 16/08; H01L 21/02

(52) U.S. Cl. CPC C23C 16/045; C23C 16/08; H10P 14/6334

(57) ABSTRACT

Methods for filling a substrate feature with a seamless fluorine free tungsten gap fill are described. Methods comprise exposing a substrate surface to a tungsten precursor and a reducing agent substantially simultaneously, wherein the dosage of the tungsten precursor is in a range of from greater than 0.2 sccm to less than 5 sccm.

### TECHNICAL FIELD

Embodiments of the disclosure generally relate to methods for filling substrate features. More particularly, embodiments of the disclosure are directed to methods for filling a substrate feature with a seamless conformal method.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. The hGAA structure provides good electrostatic control and can find broad adoption in complementary metal oxide semiconductor (CMOS) wafer manufacturing.

Parasitic sub-fin capacitance and leakage is a chronic issue of GAA transistors and FinFETs, degrading the performance of the device. To suppress the leakage and the capacitance, an isolation is needed to block the current path. In microelectronics device fabrication there is a need to fill narrow trenches having aspect ratios (AR) greater than 10:1 with no voiding for many applications. Current methods to achieve void less gap fill usually require multiple steps, e.g., cyclic deposition-etch-treatment processes, or gradient inhibition and deposition processes. Such multi-step processes, however, are problematic because they are costly and result in film impurities and other adverse film properties. Therefore, there is a need in the art for an improved method to create a seamless gap fill.

### SUMMARY

One or more embodiments of the disclosure are directed to a method of forming a fluorine free tungsten film on a substrate. The method comprises: exposing a substrate surface to a tungsten precursor and a reducing agent substantially simultaneously, wherein the dosage of the tungsten precursor is in a range of from greater than 0.2 sccm to less than 5 sccm to form the fluorine free tungsten film on the substrate.

Another embodiment of the disclosure is directed to a method of forming a fluorine free tungsten film on a substrate. The method comprises: exposing a substrate surface to a tungsten halide precursor and a reducing agent substantially simultaneously, wherein the dosage of the tungsten halide precursor is in a range of from greater than 0.2 sccm to less than 5 sccm to form the fluorine free tungsten film on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional view of a semiconductor device in accordance with one or more embodiments of the disclosure;

FIG. 1B illustrates a cross-sectional view of a semiconductor device in accordance with one or more embodiments of the disclosure;

FIG. 1C illustrates a cross-sectional view of a semiconductor device in accordance with one or more embodiments of the disclosure;

FIG. 2A illustrates a cross-sectional view of a semiconductor device in accordance with one or more embodiments of the disclosure;

FIG. 2B illustrates a cross-sectional view of a semiconductor device in accordance with one or more embodiments of the disclosure;

FIG. 2C illustrates a cross-sectional view of a semiconductor device in accordance with one or more embodiments of the disclosure;

FIG. 3 illustrates a process flow diagram in accordance with one or more embodiments of the disclosure; and

FIG. 4 illustrates a schematic top-view diagram of an example multi-chamber processing system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated Ip. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices.

As used herein, the term “3D NAND” refers to a type of electronic (solid-state) non-volatile computer storage memory in which the memory cells are stacked in multiple layers. 3D NAND memory generally includes a plurality of memory cells that include floating-gate transistors. Traditionally, 3D NAND memory cells include a plurality of NAND memory structures arranged in three dimensions around a bit line.

As used herein, the term “dynamic random access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

Embodiments of the disclosure provide methods of depositing a tungsten (W) film (e.g., fluorine free tungsten film) in high aspect ratio (AR) structures with small dimensions. Some embodiments advantageously provide methods that use a single step to achieve void less gap fill. Some embodiments advantageously provide seam-free high quality films to fill high AR trenches with small dimensions. In one or more embodiments, provided are methods of filling high AR trenches with small dimension completely or partially with a voidless gap fill material.

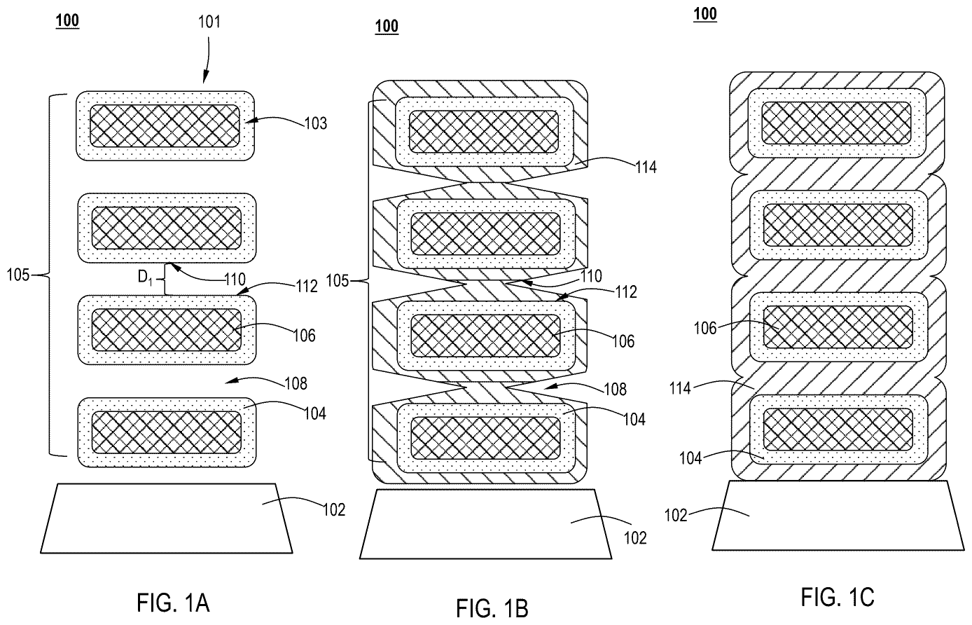

FIGS. 1A through 1C illustrate a partial cross-sectional view of a device 100, e.g., a transistor, with a feature 108. The Figures show substrates and devices having a single feature for illustrative purposes; however, those skilled in the art will understand that there can be more than one feature. The shape of the feature 108 can be any suitable shape including, but not limited to, trenches and cylindrical vias. As used in this regard, the term “feature” means any intentional surface irregularity. Suitable examples of features include, but are not limited to, trenches, which have a top, two sidewalls, and a bottom, and peaks, which have a top and two sidewalls. Features can have any suitable aspect ratio (ratio of the depth of the feature to the width of the feature). In some embodiments, the aspect ratio is greater than or equal to about 5:1, greater than or equal to about 10:1, greater than or equal to about 15:1, greater than or equal to about 20:1, greater than or equal to about 25:1, greater than or equal to about 30:1, greater than or equal to about 35:1, greater than or equal to about 40:1, greater than or equal to about 50:1, greater than or equal to about 60:1, greater than or equal to about 70:1, greater than or equal to about 80:1, greater than or equal to about 90:1, or greater than or equal to about 100:1. In one or more embodiments, the electronic device 100 includes a plurality of fins 101 and a plurality of gates 103 on the substrate surface 102.

In one or more embodiments, the at least one feature 108 comprises an opening between channel layers of a transistor, or memory hole, or a word line slit. Accordingly, in one or more embodiments, the device 100 comprises a memory device or a logic device, e.g., NAND, VNAND, DRAM, GAA, CFET, or the like.

In one or more embodiments, the device 100 has a substrate 102. In one or more embodiments, the semiconductor substrate 102 can be any suitable substrate material. In some embodiments, the substrate 102 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 102 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 102 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the substrate may be doped to provide a high dose of dopant at a first location of the surface of the substrate 102 in order to prevent parasitic bottom device turn on. In one or more embodiments, a superlattice structure 105 is formed atop the first location. For example, in some embodiments, the surface of the substrate may have a dopant density about 10¹⁸ atoms/cm³ to about 10¹⁹ atoms/cm³.

In one or more embodiments, the fins 101 comprise at least one superlattice structure 105 formed atop the top surface of the substrate 102 (as depicted in FIG. 1A). When formed, the superlattice structure 105 comprises a plurality of sacrificial layers and a corresponding plurality of channel layers 106 alternatingly arranged in a plurality of stacked pairs. In some embodiments the plurality of stacked groups of layers comprises a silicon (Si) and silicon germanium (SiGe) group. In some embodiments, the plurality of sacrificial layers and corresponding plurality of channel layers 106 can comprise any number of lattice matched material pairs suitable for forming a superlattice structure 105. In some embodiments, the plurality of sacrificial layers and corresponding plurality of channel layers 106 comprise from about 2 to about 50 pairs of lattice matched materials. As used herein, the term “channel” refers to a layer of material that is an electrical conductor. In one or more embodiments, the channel 106 comprises one or more silicon, polysilicon, amorphous silicon, doped silicon, strained silicon, silicon on insulator (SOI), carbon doped silicon dioxides, SiGe, germanium, gallium arsenide, GaN, InP, carbon nanotube, and the like.

Typically, a parasitic device, not illustrated, will exist at the bottom of the superlattice structure 105. In some embodiments, the implantation of a dopant in the substrate, as discussed above, is used to suppress the turn on of the parasitic device. In some embodiments, the substrate 102 is etched so that the bottom portion of the superlattice structure 105 includes a substrate portion which is not removed, allowing the substrate portion to act as the bottom release layer of the superlattice structure 105.

In one or more embodiments, the thicknesses of the sacrificial layers and channel layers 106 in some embodiments are in the range of from about 2 nm to about 50 nm, in the range of from about 3 nm to about 20 nm, or in a range of from about 2 nm to about 15 nm. In some embodiments, the average thickness of the sacrificial layers is within 0.5 to 2 times the average thickness of the channel layers 106.

During formation of the device 100, the sacrificial layers are removed, resulting in the formation of an opening 108 between the channel layers 106. In some embodiments, a gate dielectric layer 104 is formed on the channel layers 106. The gate dielectric layer 104 may comprise any suitable material known to the skilled artisan. In one or more embodiments, the gate dielectric layer 104 comprises silicon nitride (SiN).

The at least one feature 108 forms an opening between the channel layers 106. The at least one feature 108 has a center/inside 110 and an outer surface 112. The center/inside 110 has a thickness or depth D₁ of the at least one feature 108. The open area formed by the center/inside 110 and the outer surface 112 may also be referred to as a gap. In one or more embodiments, the depth D₁ is homogenous along the width of the at least one feature 108. In other embodiments, the depth D₁ is greater at the center/inside 110 of the at least one feature 108 than the depth D₁ at the outer surface 112 of the at least one feature 108. In still further embodiments, the depth D₁ is greater at the outer surface 112 of the at least one feature 108 than the depth D₁ at the center/inside 110 of the at least one feature 108.

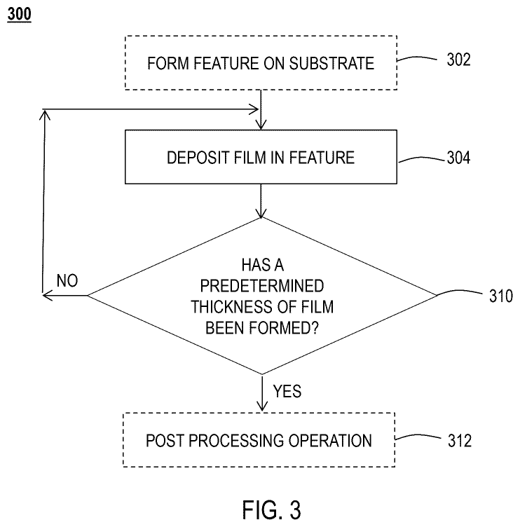

Referring to FIG. 1B and FIG. 1C, in one or more embodiments the at least one feature 108 is filled with a gap fill material 114. The gap fill material 114 may comprise any suitable material known to the skilled artisan. In one or more embodiments, the gap fill material 114 is a tungsten (W) film formed by the method illustrated in FIG. 3. In some embodiments, the gap fill material is a fluorine free tungsten (FFW) film formed by the method illustrated in FIG. 3. In some embodiments, the gap fill material 114 is advantageously a super conformal film. As used herein, the term “super conformal” refers to a layer or film which has a greater average thickness near the inside of a feature than near the outside of the feature.

In some embodiments, the gap fill material 114 is deposited super conformally on the at least one feature 108. As used in this manner, a super conformal film has a thickness near the center/inside 110 of the feature 108 that is in the range of about 100-120% or 100-110% of the thickness at the outside surface 112 of the feature 108. Stated differently, as illustrated in FIG. 1B, in one or more embodiments, the gap fill material 114 is deposited with a greater thickness at the center/inside 110 than outside surface 112 the at least one feature 108.

Referring to FIG. 1C, the method of super conformal deposition continues such that the gap fill material 114 fills the at least one feature 108. Without intending to be bound by theory, it is believed that the one-step gap fill deposition method of one or more embodiments results in a gap fill material 114 that does not have a void or seam. In one or more embodiments, the gap fill material 114 is formed without any substantial void. In this regard, the phrase “without any substantial void” means that, if an opening or void is present, the opening or void is less than or equal to 1 nm in width within the at least one feature 108. In some embodiments, the gap fill material 114 is formed within the at least one feature 108 without any substantial seam. In this regard, the phrase “without any substantial seam” means that, if a seam is present, the seam is less than or equal to 1 nm in width.

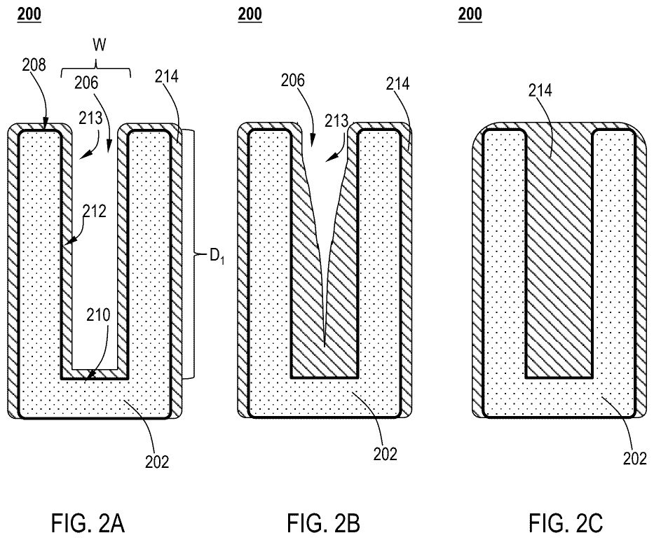

FIGS. 2A-2C illustrate cross-sectional schematic views of a substrate 202 during stages of a super conformal gap fill process with a fluorine free tungsten (FFW) film 214. FIGS. 2A-2C illustrate a cross-sectional schematic view of depositing the fluorine free tungsten (FFW) film 214 on a top surface 208, sidewall surface 210, and bottom surface 210 of the substrate 202 comprising at least one feature 206. The at least one feature 206 defines a gap having two opposed sidewalls 212, a bottom surface 208, and a top 213 portion. As will be described in further detail below, the fluorine free tungsten (FFW) film 214 is formed by a super conformal deposition method 300.

FIGS. 2A-2C show the substrate 202 having a single feature 206 for illustrative purposes; however, those skilled in the art will understand that there can be more than one feature 206. The shape of the feature 206 can be any suitable shape including, but not limited to, trenches and cylindrical vias, as described herein.

As described above, the term “feature” means any intentional surface irregularity. Suitable examples of features include, but are not limited to, trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, greater than or equal to about 10:1, greater than or equal to about 15:1, greater than or equal to about 20:1, greater than or equal to about 25:1, greater than or equal to about 30:1, greater than or equal to about 35:1, greater than or equal to about 40:1, greater than or equal to about 50:1, greater than or equal to about 60:1, greater than or equal to about 70:1, greater than or equal to about 80:1, greater than or equal to about 90:1, or greater than or equal to about 100:1.

In one or more embodiments, the at least one feature 206 comprises a memory hole or a word line slit. Accordingly, in one or more embodiments, the device 100 comprises a memory device or a logic device, e.g., NAND, VNAND, DRAM, GAA, CFET, or the like.

Referring to FIG. 2B, in one or more embodiments the at least one feature 206 is filled with a gap fill material 214. The gap fill material 214 may comprise any suitable material known to the skilled artisan. In one or more embodiments, the gap fill material 214 is a tungsten (W) film formed by the method illustrated in FIG. 3. In some embodiments, the gap fill material 214 is a fluorine free tungsten (FFW) film formed by the method illustrated in FIG. 3. In some embodiments, the gap fill material 214 is advantageously a super conformal film. As used herein, the term “super conformal” refers to a layer or film which has a greater average thickness near the bottom of a feature than near the top of the feature.

In some embodiments, the gap fill material 214 is deposited super conformally in the at least one feature 206. As used in this manner, a super conformal film has a thickness near the bottom 210 of the feature 206 that is in the range of about 100-120% or 100-110% of the thickness at the top 213 of the feature 206. Stated differently, in some embodiments, the gap fill material 214 is deposited with a greater thickness at the bottom 210 than the top 213 of the at least one feature 206.

Some embodiments of the disclosure are directed to methods for zip-up gap fill of a feature, e.g., of at least one feature 206. A zip-up gap fill process primarily fills the feature 206 from the bottom 210 with some fill from the sides 212, versus a conformal process which primarily fills the feature 206 from the bottom 210 and sides 212 at the same rate. In some embodiments, the super conformal deposition in the feature results in greater deposition near the bottom 210 of the feature than near the top 213 portion of the feature 206, resulting in zip-up gap fill to fill the feature 206 substantially without a seam or void.

Without intending to be bound by theory, it is believed that the one-step gap fill deposition method of one or more embodiments results in a gap fill material 214 that does not have a void or seam, as illustrated in FIG. 2C. In one or more embodiments, the gap fill material 214 is formed without any substantial void. In this regard, the phrase “without any substantial void” means that, if an opening or void is present, the opening or void is less than or equal to 1 nm in width within the at least one feature 206. In some embodiments, the gap fill material 214 is formed within the at least one feature 206 without any substantial seam. In this regard, the phrase “without any substantial seam” means that, if a seam is present, the seam is less than or equal to 1 nm in width.

FIG. 3 illustrates a process flow diagram of a method 300 according to one or more embodiments. In one or more embodiments, referring to FIGS. 1A-1C, FIGS. 2A-2C, and FIG. 3, at operation 302, at least one feature 108, 206 is formed in a device 100, 200. In some embodiments, the semiconductor device 100, 200 is provided for processing. As used in this regard, the term “provided” means that the substrate is placed into a position or environment for further processing. In one or more embodiments, the semiconductor device 100, 200 has at least one feature 108, 206 already formed therein. In other embodiments, at operation 302, at least one feature 108, 206 is formed on/in semiconductor device 100, 200. In one or more embodiments, the at least one feature 108, 206 extends a feature height or depth, D₁.

In one or more embodiments, at operation 304, a gap fill film 114, 214 is formed on or in the at least one feature 108, 206. In one or more embodiments, the gap fill film 114, 214 may be free of a void or a gap within the width, W, and depth, D₁, of the at least one feature 108, 206.

In one or more embodiments, the gap fill material 114, 214 is formed by a chemical vapor deposition (CVD) process. Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity. In one or more embodiments, the method comprises a one-step chemical vapor deposition (CVD) process in which the reactive gases are mixed in the processing chamber to allow gas phase reactions of the reactive gases and deposition of the thin film.

One or more embodiments use fluorine-free metal precursors to increase selectivity and deposition rate to form the gap fill material 114, 214. Some embodiments incorporate a reducing agent in the CVD process to increase the selectivity relative to dielectrics and increase the deposition rate with comparable film performance (e.g., step coverage, gap filling). Some embodiments provide high selectivity fluorine-free tungsten deposition with high throughput CVD processes.

One or more embodiments of the disclosure incorporate different gases (e.g., H₂, SiH₄, Si₂H₆, Si₄H₁₀, NH₃) into the metal (e.g., tungsten (W)) precursor dose. In some embodiments, the incorporation of a reducing agent improves the selectivity of the metal deposition relative to dielectrics and accelerates the rate of metal reduction.

In some embodiments, CVD fluorine-free tungsten (FFW) has low resistivity, excellent step coverage, superior fluorine barrier property, and can integrate with conventional WF₆ based bulk W fill. Some embodiments improve throughput while maintaining acceptable film performance or other metrics (e.g., non-uniformity, step coverage, particles).

One or more embodiments of the disclosure are directed to methods with deposition rates in a range of from greater than 0 A/s to 0.5 A/s, or in a range of from greater than 0.1 A/s to 0.5 A/s, or in a range of from 0.2 A/s to 0.5 A/s, or in a range of from 0.25 A/s to 0.45 A/s.

A small coflow of a reducing agent, like H₂, SiH₄, Si₂H₆, Si₄H₁₂, NH₃, is added to the W precursor CVD process. In some embodiments, the growth of FFW with a hydrogen (H₂) coflow by CVD occurs at a suitable temperature (e.g., ranging from 400° C. to 550° C., or from 460° C. to 475° C.).

The tungsten precursor for growing FFW includes, but is not limited to, tungsten chloride and hydrogen as reducing agent. In one or more embodiments, the one step CVD process includes exposure to a tungsten (W) precursor dose in a range of from greater than 0.2 sccm to less than 5.0 sccm, including in a range of from 0.3 sccm to 4.5 sccm, or a range of from 0.5 sccm to 4.0 sccm. In specific embodiments, as illustrated in the Example, the tungsten precursor is tungsten halide and the one step CVD process includes exposure to tungsten halide dose in dose in a range of from greater than 0.2 sccm to less than 5.0 sccm, including in a range of from 0.3 sccm to 4.5 sccm, or a range of from 0.5 sccm to 4.0 sccm.

In one or more embodiments, the one step CVD process includes 50 sccm to 10,000 sccm, or 3000 sccm to 10,000 sccm of H₂ coflow. Argon (Ar) or other suitable inert gas may be used for precursor carrier.

In one or more embodiments, the tungsten precursor comprises or consists essentially of a tungsten halide. As used herein, the term “halide” refers to a binary phase, of which one part is a halogen atom and the other part is an element or radical that is less electronegative than the halogen, to make a fluoride, chloride, bromide, or iodide compound. A halide ion is a halogen atom bearing a negative charge. As known to those of skill in the art, a halide anion includes fluoride (F—), chloride (Cl—), bromide (Br—), and iodide (I—). Thus, in one or more embodiments, the tungsten halide precursor may comprise any suitable compound containing tungsten (W) and a halide selected from chloride (Cl—), bromide (Br—), and iodide (I—).

In some embodiments, the tungsten halide comprises one or more of tungsten pentachloride (WCl₅) or tungsten hexachloride (WCl₆). In some embodiments, the fluorine-free tungsten precursor comprises a tungsten oxy-halide precursor, such as tungsten oxytetrachloride (WOCl₄) or tungsten dichloride dioxide (WO₂Cl₂). In other embodiments, the process condition comprises a tungsten precursor selected from the group consisting of fluorine free tungsten halide precursors or chlorine-free tungsten halide precursors, such as tungsten pentabromide (WBr₅) or tungsten hexabromide (WBr₆).

In some embodiments, the tungsten film is a fluorine free tungsten film and contains essentially no fluorine atoms. As used in this manner, the term “contains essentially no fluorine atoms” means the tungsten film comprises less than or equal to about 2%, 1% or 0.5% of fluorine atoms on an atomic basis. In some embodiments, the tungsten film is free of fluorine atoms.

The method of forming the tungsten nucleation layer may further comprise flowing a first reducing agent that is reactive with the tungsten precursor. The first reducing agent (also referred to as a first reductant) comprises a reactive gas, such as a hydrogen-containing gas, such as hydrogen (H₂) or ammonia (NH₃) or hydrazine N₂H₄), and a carrier gas, such as argon (Ar), helium (He), or nitrogen (N₂). In some embodiments, the carrier gas is an inert gas. In some embodiments, the first gas consists of, or consists essentially of, a metallic tungsten precursor gas, a reactant gas, and a carrier gas. In some embodiments, the first gas consists of, or consists essentially of a chlorine-free, fluorine-free tungsten halide precursor, a hydrogen containing gas, and an inert gas. In some embodiments, the first reducing agent comprises one or more of hydrogen (H₂), silane (SiH₄), disilane (Si₂H₆), trisilane (Si₃H₈), tetrasilane (Si₄H₁₀) or ammonia (NH₃).

The tungsten precursor of some embodiments is flowed into the process region of the processing chamber in a carrier gas. For solid or liquid precursors, the precursors of some embodiments are held in an ampoule and a flow of carrier gas passes through the ampoule and brings precursor along. In some embodiments, the carrier gas comprises an inert gas. In some embodiments, the carrier gas comprises or consists essentially of one or more of helium, neon, argon, nitrogen, krypton or xenon. As used herein, the flow rate of the metal precursor is the flow rate of the carrier gas including the metal precursor.

The total flow into the process region of the processing chamber according to some embodiments is the combined flow rates of the metal precursor and the first reducing agent. In some embodiments, a make-up gas is flowed into the process region and the metal precursor and the first reducing agent are added to the make-up gas flow stream. In some embodiments, the make-up gas flow stream is at a much larger flow rate than either the metal precursor or the first reducing agent. In some embodiments, the make-up gas flow stream has a flow rate greater than 10× the higher of the precursor flow or the first reducing agent flow.

In some embodiments, the fluorine-free tungsten precursor and the reducing agent have a flow rate ratio in the range of from 1:1000 to 1:10000. Flowing the tungsten precursor and the reducing agent may result in the formation of a tungsten monolayer of the tungsten gap fill material.

In some embodiments, the substrate is exposed to the tungsten precursor and the reducing agent at any suitable pressure. In one or more embodiments, the pressure is in a range of from 15 Torr to 100 Torr. In more specific embodiments, the range of pressure in the substrate processing chamber, such as an CVD chamber, during deposition of the tungsten film is in a range of from 15 Torr to 100 Torr.

At decision 310, the thickness of the deposited fluorine free tungsten gap fill film 114, 214 is considered. If the deposited fluorine free tungsten gap fill film 114, 214 has reached a predetermined thickness or a predetermined number of process cycles have been performed, the method 300 moves to an optional post-processing operation 312. If the thickness of the deposited fluorine free tungsten gap fill film 114, 214 has not reached the predetermined threshold, the method 300 returns to operation 304 to deposit additional fluorine free tungsten gap fill film 114,214.

In some embodiments, the substrate is moved from a first chamber to a separate, next chamber for further processing. The substrate can be moved directly from the first chamber to the separate processing chamber, or the substrate can be moved from the first chamber to one or more transfer chambers and then moved to the separate processing chamber. Accordingly, the processing apparatus may comprise multiple chambers in communication with a transfer station. An apparatus of this sort may be referred to as a “cluster tool” or “clustered system”, and the like.

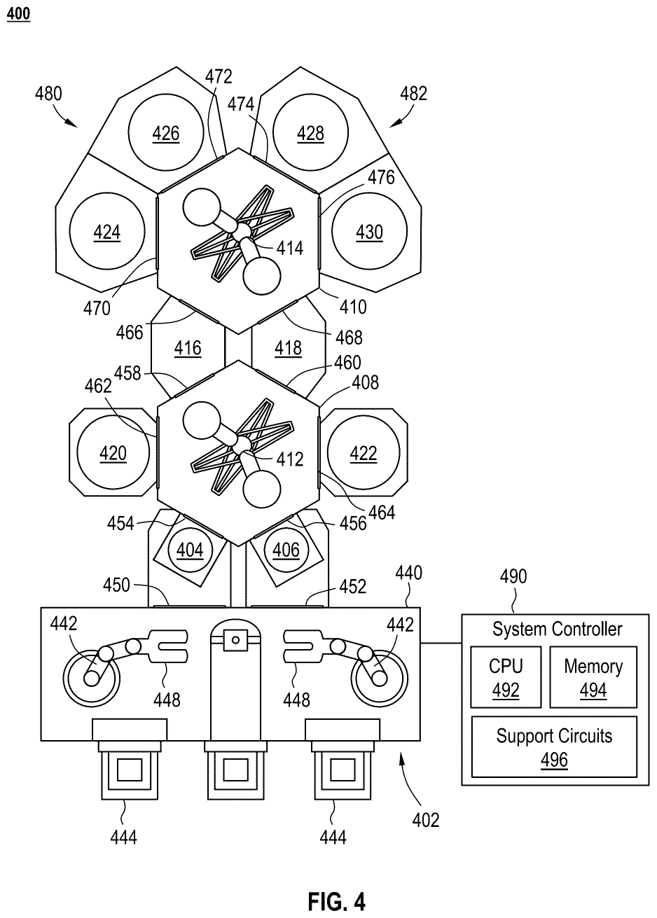

Generally, a cluster tool is a modular system comprising multiple chambers which perform various functions including substrate center-finding and orientation, degassing, annealing, deposition and/or etching. FIG. 4 illustrates a schematic top-view diagram of an example of a multi-chamber processing system, e.g., a cluster tool 400, according to embodiments of the present disclosure. The cluster tool 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the cluster tool 400 can be processed in and transferred between the various chambers without exposing the wafers to an ambient environment exterior to the cluster tool 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the cluster tool 400. Accordingly, the cluster tool 400 may provide for an integrated solution for some processing of wafers, e.g., semiconductor substrates.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes. The processing chamber 422 may be a preclean chamber. The processing chamber 420 may be an etch chamber.

A system controller 490 is coupled to the cluster tool 400 for controlling the cluster tool 400 or components thereof. For example, the system controller 490 may control the operation of the cluster tool 400 using a direct control of the chambers 404, 406, 408, 416, 418, 410, 420, 422, 424, 426, 428, 430 of the cluster tool 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the cluster tool 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

### EXAMPLES

### Super Conformal Deposition of Fluorine Free Tungsten Films

General procedure: A silicon substrate was placed in a processing chamber. A tungsten halide precursor was flowed into the processing chamber in an atmosphere of argon (Ar) gas over the silicon substrate leaving a tungsten halide-precursor terminated surface. A reducing agent was introduced into the chamber that reacted with the surface-bound tungsten species. The resultant material on the substrate was a fluorine free tungsten film.

| | Tungsten Halide | Seam Size |
|---|---|---|
| Example # | Dosage (sccm) | Results |
| 1 | 0.8 sccm | 5.3 nm |
| 2 | 1.9 sccm | 2.5 nm |
| 3 | 2.6 sccm | 0.8 nm |

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming a fluorine free tungsten film on a substrate, the method comprising:
exposing a substrate surface to a tungsten precursor and a reducing agent substantially simultaneously, wherein a dosage of the tungsten precursor is in a range of from greater than 0.2 sccm to less than 5 sccm to form the fluorine free tungsten film on the substrate.

2. The method of claim 1, wherein the dosage of the tungsten precursor is in the range of from greater than 0.3 sccm to less than 4.5 sccm.

3. The method of claim 1, wherein the dosage of the tungsten precursor is in the range of from 0.5 sccm to 4.0 sccm.

4. The method of claim 1, wherein the tungsten precursor comprises a tungsten halide.

5. The method of claim 4, wherein the tungsten halide comprises one or more of tungsten pentachloride (WCl₅) or tungsten hexachloride (WCl₆).

6. The method of claim 5, wherein the tungsten halide comprises tungsten pentachloride (WCl₅).

7. The method of claim 1, wherein the tungsten precursor a tungsten oxy-halide precursor.

8. The method of claim 7, wherein the tungsten oxy-halide precursor comprises one or more of tungsten oxytetrachloride (WOCl₄) or tungsten dichloride dioxide (WO₂Cl₂).

9. The method of claim 1, wherein the tungsten precursor is selected from the group consisting of fluorine free tungsten halide precursors or chlorine-free tungsten halide precursors.

10. The method of claim 9, wherein the tungsten precursor comprises one or more of tungsten pentabromide (WBr₅) or tungsten hexabromide (WBr₆).

11. The method of claim 1, wherein the reducing agent comprises one or more of H₂, SiH₄, Si₂H₆, Si₄H₁₂, NH₃.

12. The method of claim 1, wherein the fluorine free tungsten film has essentially no fluorine atoms.

13. The method of claim 1, wherein the fluorine free tungsten film comprises less than or equal to about 2% of fluorine atoms on an atomic basis.

14. The method of claim 1, wherein the substrate is exposed at a pressure in a range of from 15 Torr to 100 Torr.

15. The method of claim 1, wherein the substrate is exposed at a temperature in a range of from 400° C. to 550° C.

16. A method of forming a fluorine free tungsten film on a substrate, the method comprising:
exposing a substrate surface to a tungsten halide precursor and a reducing agent substantially simultaneously, wherein the dosage of the tungsten halide precursor is in a range of from greater than 0.2 sccm to less than 5 sccm to form the fluorine free tungsten film on the substrate.

17. The method of claim 16, wherein the dosage of the tungsten halide precursor is in the range of from 0.5 sccm to 4.0 sccm.

18. The method of claim 16, wherein the tungsten halide precursor comprises one or more of tungsten pentachloride (WCl₅), tungsten hexachloride (WCl₆), tungsten oxytetrachloride (WOCl₄), tungsten dichloride dioxide (WO₂Cl₂), tungsten pentabromide (WBr₅), and tungsten hexabromide (WBr₆).

19. The method of claim 16, wherein the reducing agent comprises one or more of H₂, SiH₄, Si₂H₆, Si₄H₁₂, NH₃.

20. The method of claim 16, wherein the fluorine free tungsten film comprises less than or equal to about 2% of fluorine atoms on an atomic basis.
